(19) United States
(12) Patent Application Publication
(10) Pub. No.: US 2006/0081943 A1
(43) Pub. Date: Apr. 20, 2006

(54) Semiconductor device and method for the preparation thereof

(76) Inventor: Yuri Masuoka, Kanagawa (JP)

Correspondence Address: YOUNG & THOMPSON, 745 SOUTH 23RD STREET, 2ND FLOOR, ARLINGTON, VA, 22202, US

(21) Appl. No.: 11/248,209

(22) Filed: Oct. 13, 2005

(30) Foreign Application Priority Data
Oct. 14, 2004 (JP) 2004-300192

(51) Int. Cl. H01L 29/76

(52) U.S. Cl. 257/388

(57) ABSTRACT

A semiconductor device in which penetration of a metal silicide film in a source/drain layer as well as generation of the leakage current is suppressed. A semiconductor device includes a gate 6, formed only of a metal silicide, and a metal silicide layer 10, formed on a source/drain layer 9. The metal silicide layer is thinner in the thickness than the gate 6 and contains a silicidation suppressing component for suppressing the silicidation of the silicon substrate 2.

### FIELD OF THE INVENTION

This invention relates to a semiconductor device employing a silicide gate, and a method for the preparation thereof. More particularly, it relates to a semiconductor device in which it is possible to suppress penetration of a metal silicide film in a source/drain layer 10 or generation of the leakage current, and a method for the preparation thereof.

### BACKGROUND OF THE INVENTION

In a MISFET, inclusive of a MOSFET, miniaturization proceeds for increasing the operating speed, such that it is crucial to suppress the phenomenon of gate depletion as much as possible. Hence, it is most desirable to use a metal gate in place of a polysilicon gate, inclusive of a polycide gate, a salicide gate, or a gate a portion of which has been silicided (see Patent Document 1). However, the metal gate leaves much to be desired, such as overcoming the problem of production techniques attendant on miniaturization, or assuring high reliability, and is difficult to realize. For this reason, a silicide gate, employing only metal silicide as a gate material, has come to be used in order to resolve the phenomenon of gate depletion and in order to assure ease in production techniques, high operational precision and reliability and low cost onus. Among instances of the related art, employing a silicide gate, there is a MIS semiconductor device including a semiconductor substrate, a source/drain region formed with a channel region on the substrate surface in-between, a gate insulating film formed on the channel region, and a gate electrode, formed only of a metal silicide film, and formed on the gate insulating film (see Patent Document 2).

[Patent Document 1 ]

JP Patent Kokai Publication No. JP-A-11-111980

[Patent Document 2 ]

JP Patent Kokai Publication No. JP-P2000-252462A

### SUMMARY OF THE DISCLOSURE

However, in the Patent Document 2, a metal silicide is substituted for polysilicon, as a gate, at the same time as a metal silicide is substituted for a portion up to a certain depth from the surface of a deep junction of the source/drain region. Thus, in a miniaturized structure, if silicidation is carried out until the metal silicide is substituted for the entire gate, there is a risk that a metal silicide film is formed as it penetrates the junction interface of the source/drain region with a well or the channel region. Even granting that the metal silicide film is suppressed from penetrating the junction interface of the source/drain region, the current leaks from the metal silicide film to the well or the channel region (junction leakage) thus causing malfunctions in the device operations or increasing the power consumption.

It is an object of the present invention to suppress penetration of the metal silicide film in the source/drain region or generation of the leakage current.

In a first aspect, the present invention provides a semiconductor device comprising a gate formed only of a metal silicide, and a metal silicide film formed on a source/drain layer, the metal silicide film being lesser in film thickness than the gate and containing a silicidation suppressing component for suppressing the silicidation of a silicon substrate.

In a second aspect, the present invention provides a semiconductor device comprising a silicon substrate, a source/drain layer formed so that a source and a drain are on both sides of a channel region of the silicon substrate, a gate insulating film formed on the channel region, a gate formed only of a metal silicide, and provided on the gate insulating film, and a metal silicide layer thinner in the thickness than the gate. The metal silicide layer is formed on the source/drain layer and contains a silicidation suppressing component for suppressing the silicidation of the silicon substrate.

In a third aspect, the present invention provides a method for the preparation of a semiconductor device comprising the steps of: selectively introducing a silicidation suppressing component, suppressing the silicidation, into at least one area of a source/drain layer; coating at least a gate, formed of polysilicon or amorphous silicon, and the source/drain layer, with metal having a film thickness sufficient for silicidation of the gate in its entirety; and metal-siliciding the gate in its entirety by heat treatment and also metal-siliciding at least the area of the source/drain layer into which has been introduced the silicidation suppressing component.

In a fourth aspect, the present invention provides a method for the preparation of a semiconductor device comprising: the steps of: selectively forming a silicidation adjustment film, composed of a silicidation suppressing component- for suppressing the silicidation; and a silicon component, on at least one area of a source/drain layer;

coating at least a gate formed of polysilicon or amorphous silicon, and the silicidation adjustment film, with metal to a film thickness sufficient for silicidation of the gate in its entirety; and

metal-siliciding the gate in its entirety and simultaneously metal-siliciding at least the silicidation adjustment film, by heat treatment.

In a fifth aspect, the present invention provides a method for the preparation of a semiconductor device comprising the steps of: forming at least a region of device separating layer in a silicon substrate, forming a gate insulating film in a channel region in the silicon substrate, forming a gate of polysilicon or amorphous silicon on the gate insulating film, forming a hard mask on the gate, the hard mask being formed of a material different in an etch rate from the device separating layer, selectively forming a source/drain layer in the silicon substrate on both sides of the gate, selectively introducing a silicidation suppressing component for suppressing the silicidation, into the source/drain layer, removing the hard mask, coating at least the gate and the source/drain layer with metal of a film thickness at least sufficient for siliciding the gate in its entirety, metal-siliciding the gate in its entirety and simultaneously metal-siliciding at least an area of the source/drain layer, into which the silicidation suppressing component has been introduced, by heat treatment, and selectively removing a non-reacted portion of the metal.

In a fifth aspect, the present invention provides a method for the preparation of a semiconductor device comprising the steps of: forming at least a region of device separating layer in a silicon substrate, forming a gate insulating film in a channel region in the silicon substrate; forming a gate of polysilicon or amorphous silicon on the gate insulating film; forming a hard mask on the gate, the hard mask being formed of a material different in an etch rate from the device separating layer; selectively forming a source/drain layer in the silicon substrate on both sides of the gate; selectively forming a silicidation adjustment film, containing a silicidation suppressing component for suppressing the silicidation of the silicon substrate, and a silicon component; on the source/drain layer; removing the hard mask; coating at least the gate and the silicidation adjustment film with metal to a film thickness sufficient for siliciding the gate in its entirety; metal-siliciding the gate in its entirety and simultaneously metal-siliciding at least the silicidation adjustment film, by heat treatment; and selectively removing a non-reacted portion of the metal.

The meritorious effects of the present invention are summarized as follows.

According to the present invention (1st through 6th aspects), a structure of thin film thickness of a silicide film of the source/drain may be achieved by a simplified method as a fully silicided gate structure is provided. That is, a fully silicided gate structure is achieved using a conventional flow for CMOS fabrication.

According to the present invention (3rd through 6th aspects), the film thickness of the metal silicide film on the source/drain layer may be freely set, by setting the concentration of the silicidation suppressing component and the film thickness of the region, to which has been introduced the silicidation suppressing component, thus prohibiting the junction leakage.

According to the present invention (4th through 6th aspects), full gate silicidation as well as silicidation of the silicidation adjustment film may be achieved simultaneously simply by adding the step of adding the silicidation adjustment film to the conventional flow for CMOS fabrication. This dispenses with PR or etching for forming a metal silicide film on the source/drain layer, thus appreciably reducing the number of process steps. Moreover, there is no necessity of a separate formation step of the gate (full silicide gate) from that of the metal silicide film on the source/drain layer because the reaction rate difference brought about by the silicidation suppressing component is exploited.

According to the present invention (4th through 6th aspects), the junction leakage may be prohibited because the film thickness of the metal silicide film on the source/drain layer may be freely set by the setting of the film thickness of the silicidation adjustment film.

According to a particular feature of the present invention (refer to claims 6 and 15), the threshold voltage or the gate work function may be adjusted, as the constant impurity concentration in the silicon substrate is maintained, by metal-siliciding the gate into which is introduced an impurity to a preset concentration.

According to a specific feature of the present invention (refer to claims 8, 9, 16 and 17), the threshold voltage or the gate work function may be set to respective optimum values, from one device forming region to another, by varying the impurity in the gate or the impurity concentration, from one device forming region to another.

### BRIEF DESCRIPTION OF THE DRAWINGS

FIG. 1 is a partial cross-sectional view schematically showing the configuration of a semiconductor device according to a first embodiment of the present invention.

FIGS. 2A, 2B and 2C are partial cross-sectional views schematically showing a first stage of the method for the preparation of the semiconductor device according to a first embodiment of the present invention.

FIGS. 3A, 3B and 3C are partial cross-sectional views schematically showing a second stage of the method for the preparation of the semiconductor device according to the first embodiment of the present invention.

FIGS. 4A, 4B and 4C are partial cross-sectional views schematically showing a third stage of the method for the preparation of the semiconductor device according to the first embodiment of the present invention.

FIGS. 5A, 5B and 5C are partial cross-sectional views schematically showing the configuration of a semiconductor device according to the first embodiment of the present invention.

FIG. 6 is a partial cross-sectional view schematically showing the configuration of a semiconductor device according to a second embodiment of the present invention.

FIGS. 7A, 7B and 7C are partial cross-sectional views showing the process steps of a method for the preparation of a semiconductor device according to the second embodiment of the present invention.

### PREFERRED EMBODIMENTS OF THE INVENTION

### First Embodiment

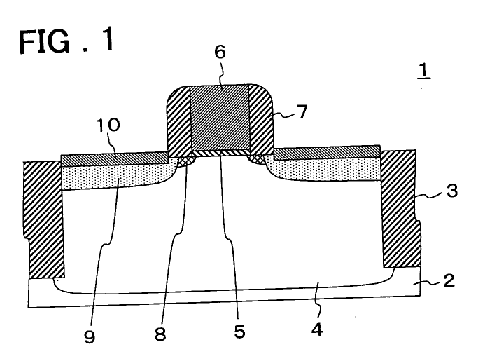

Referring to the drawings, a first embodiment of the present invention will now be explained. FIG. 1 depicts a partial cross-sectional view schematically showing the configuration of a semiconductor device according to a first embodiment of the present invention.

In this semiconductor device 1, there are formed device separating regions 3, formed of a silicon oxide film, on a silicon substrate 2, and a well 4, in which an impurity has been diffused, is formed in a device forming region disposed between the device separating regions 3. A gate insulating film 5 is formed in a channel region in the device forming region. On the gate insulating film 5, there is formed a gate 6 formed only of metal silicide. A sidewall 7 is formed on each side of the gate 6. In the well 4, below the sidewall 7, there is formed a shallow LDD (Lightly Doped Drain) layer 8, into which an impurity has been diffused at a low concentration. On the outer side of the LDD layer 8, there is formed a pair of areas of deep source/drain layer 9, into which an impurity has been diffused at a high concentration. On the top of each source/drain layer 9 is formed a metal silicide film 10, formed of metal silicide.

The silicon substrate 2 is an N type silicon substrate or a P type silicon substrate. The device separating regions 3 operate for electrically separating plural device active regions (devices) formed on the silicon substrate 2 from one another. The device separating regions 3 are formed of an insulating material, such as silicon oxide film, and are each formed to a preset depth at a location surrounding the device active regions. The well 4 represents a region in the silicon substrate 2 into which the P type or N-type impurity, such as boron ion as the P type impurity, has been diffused to a preset depth in the silicon substrate 2 from one device active region to another. For the gate insulating film 5, an insulating film, such as a silicon oxide film, a silicon nitride film, a nitride-oxide film or a high dielectric constant film, for example, is used. The gate insulating film 5 has a film thickness of, for example, 0.5 to 10 nm.

For the gate 6, a metal silicide, which is a silicide of a high melting metal, such as nickel (Ni), cobalt (Co), platinum (Pt), palladium (Pd) or rhodium (Rh), is used. The gate has a length and a thickness of, for example, not larger than 0.1 nm and not larger than 150 nm, respectively. The P type or N-type impurity may be introduced at a preset concentration into the gate 6. By so doing, the impurity concentration of the channel region may be lowered, such that the work function or the threshold voltage may be adjusted solely by adjusting the concentration of the impurity in the gate 6. For example, if Ge is used as impurity, silicidation may be suppressed, such that there may be produced a silicide structure, such as NiSi₂, containing a lesser quantity of metal components, thus providing a smaller work function. If As is used as impurity, silicidation may be promoted, such that there may be produced a silicide structure, such as NiSi, containing a larger quantity of metal components, thus providing a larger work function. If P is implanted, the Fermi level of the gate shifts towards a conduction band side, with the result that the threshold value of the NMOS is lowered. If no impurity is implanted, the Fermi level shifts to a mid part between the conduction band and the valence electron band, with a result that the threshold value of the NMOS is raised. If with the PMOS, B is implanted, the Fermi level shifts towards the valence electron band, with the result that the threshold value of the PMOS is lowered.

The sidewall 7 is formed e.g. by a silicon oxide film, and serves as a mask for preventing diffusion of the impurity to the LDD layer 8 lying in the vicinity of the channel region when forming the source/drain layer 9. The LDD layer 8 is a low density diffusion layer formed by diffusion of an impurity of the same conductivity type as that of the source/drain layer 9, for example, a phosphorus ion in case the conductivity type is the N-type. An extension layer may also be used in place of the LDD layer 8. The source/drain layer 9 is a high concentration diffusion layer into which has been diffused an impurity of the same conductivity type as that of the LDD layer 8. This impurity is e.g. an arsenic ion in case the conductivity type is the N-type. From the perspective of suppressing the generation of the leakage current, the thickness of the source/drain layer 9 is preferably 5 nm or more from the underside of the metal silicide film 10.

For the metal silicide film 10, similarly to the gate 6, a metal silicide, which is a silicide of a high melting metal, such as nickel (Ni), cobalt (Co), platinum (Pt), palladium (Pd) or rhodium (Rh), is used. In the metal silicide film 10, there has been introduced a silicidation suppressing component, such as Ge or As, suppressing the silicidation of the silicon substrate 2. The film thickness of the metal silicide film 10 is thinner than the film thickness of the gate 6. Also, the film thickness of the metal silicide film 10 is thinner than the depth of junction of the source/drain layer 9, and a film thickness not less than 3 nm, for example, is sufficient as the film thickness of the metal silicide film 10.

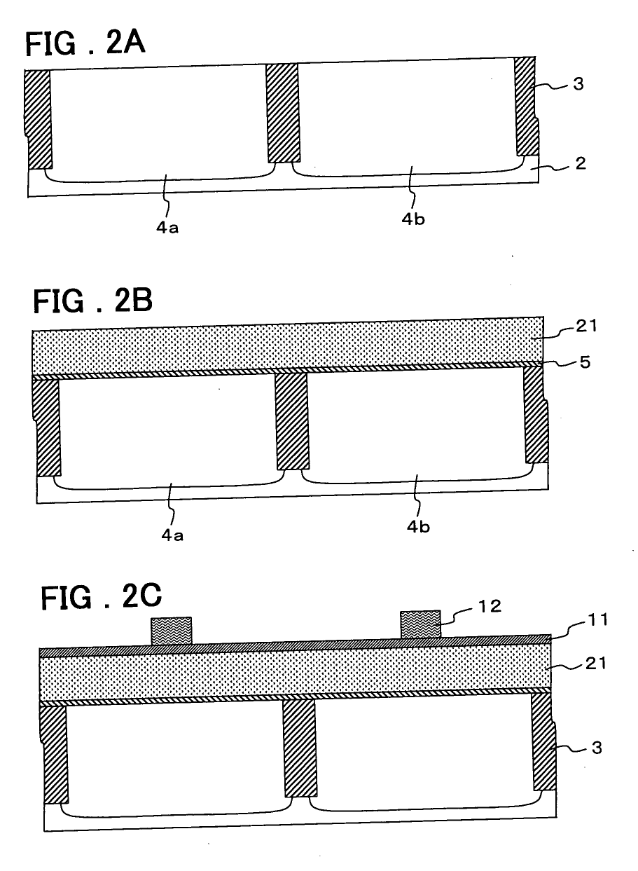

The method for the preparation of a semiconductor device of the first embodiment will now be explained. FIGS. 2A-2C, 3A-3C and 4A-4C are cross-sectional views schematically showing the steps of the method for the preparation of the semiconductor device of the first embodiment of the present invention.

First, a silicon substrate 2 is provided, and device separating regions 3 are formed at preset locations of the silicon substrate 2. A P-well 4a is selectively formed in a first device forming region (NMOS forming region) of the silicon substrate 2, and an N-well 4b is formed in a second device forming region (PMOS forming region) of the silicon substrate 2 (step A1, see FIG. 2A). As the silicon substrate 2, the P type silicon substrate, having the resistivity of e.g. 15 Ω• cm, is used. The device separating regions 3 are formed by a silicon oxide film and may be formed by the LOCOS (Local Oxidation of Silicon) method or by the STI (Shallow Trench Isolation) method. The depth of the device separating regions 3 is of the order of 0.1 to 5 μm. The P-well 4a is formed by implant of, e.g. boron (B) ions, while the N-well 4b is formed by implant of, e.g.,. phosphorus (P) ions.

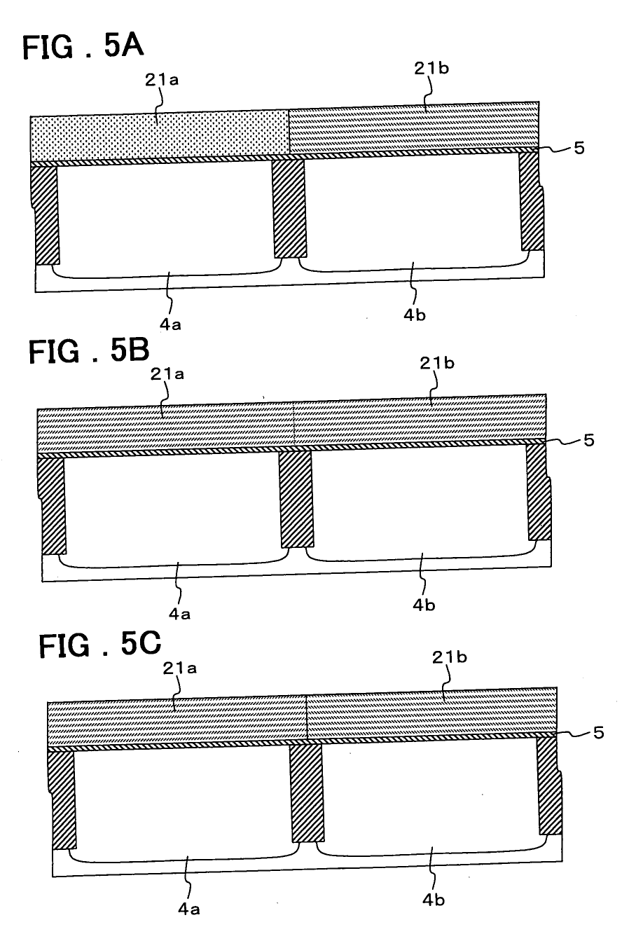

The gate insulating film 5 is then formed on the wells 4a, 4b and a silicon layer 21 for the gate then is formed on the gate insulating film 5 (step A2, see FIG. 2B). The gate insulating film 5 is a silicon oxide film by the thermal oxidation method or the LPCDV method, with a film thickness thereof being 2.5 to 3 nm. The silicon layer 21 is composed of, e.g. polysilicon or amorphous silicon, and is formed to a film thickness not larger than 150 nm on the entire surface of the gate insulating film 5. The impurity of the silicon layer 21 may be doped/annealed, after forming the silicon layer 21, for adjusting the gate work function or the threshold voltage. For example, (1) a partial region of the silicon layer 21 (a silicon layer 21b) may be doped with the impurity (see FIG. 5A), (2) the entire region of the silicon layer 21 (silicon layers 21a, 21b) may be doped with the impurity (see FIG. 5B), (3) the silicon layer 21 may be selectively doped with plural impurities differing from one device forming region to another (see FIG. 5C), or (4) the silicon layer may be doped with the same impurity to different concentrations from one device forming region to another. Of course, the silicon layer 21 does not have to be doped with the impurity if such doping is unnecessary.

Next, a hard mask 11 is formed on the silicon layer 21, and a photoresist 12 for forming the gate is formed on the hard mask 11 (step A3, see FIG. 2C). For the hard mask 11, such a material having an etch rate different from the etch rate of the device separating regions 3 is used. Such material may, for example, be a silicon nitride film, with a film thickness not larger than 100 nm. The photoresist 12 is formed by applying a photoresist material, followed by patterning the photoresist material by, e.g. the photolithographic method.

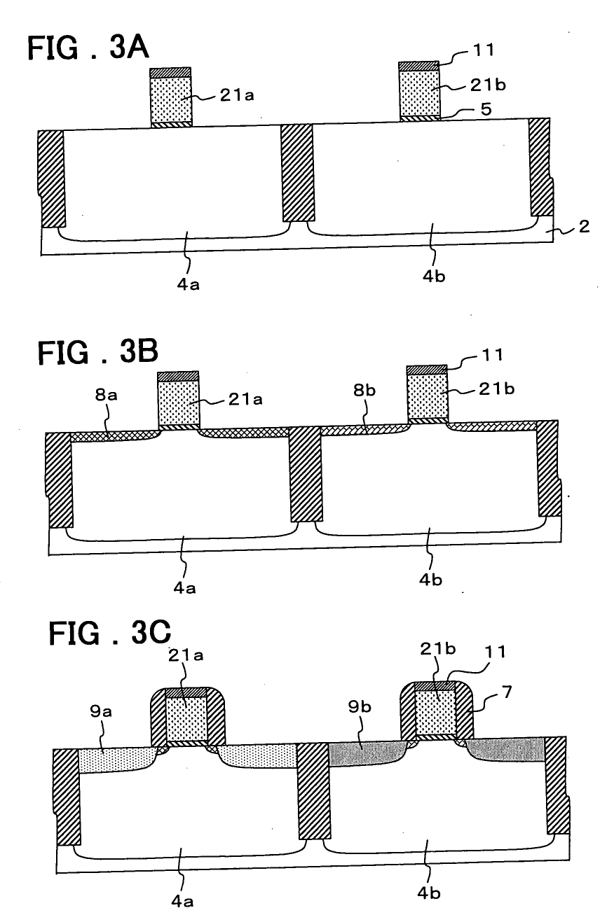

The hard mask 11 then is etched off in a region exposed from (i.e. other than) the photoresist (12 of FIG. 2C). Then, after removing the photoresist, the silicon layer (21 of FIG. 2C) and the gate insulating film 5 are etched off, with the hard mask 11 as an etching mask, until the silicon substrate 2, more precisely the wells 4a, 4b thereof are exposed (step A4, see FIG. 3A). The silicon layers 21a, 21b, thus left over, become the gates.

LDD layers 8a, 8b then are formed in preset regions in the wells 4a, 4b (step A5, see FIG. 3B). It should be noted that the LDD layer 8a is formed by diffusing the N type impurity of low concentration, such as arsenic (As) ions, in the well 4a to a shallow depth, by an ion implantation method. The LDD layer 8b is formed by diffusing the P type impurity of low concentration, such as boron (B) ions, in the well 4b to a shallow depth, by an ion implantation method. In the step A4, the hard mask 11 is left over on the silicon layers 21a, 21b.

The sidewall 7 is then formed around the lateral side of each of the silicon layers 21a, 21b, and source/drain layers 9a, 9b are formed in the wells 4a, 4b, respectively (step A6, see FIG. 3C). The sidewall 7 is formed e.g. by a silicon oxide film so as to fully covers the lateral side of the silicon layers 21a, 21b and the hard masks 11 disposed thereon, e.g. to a film thickness of 150 nm. The sidewall 7 may be formed by depositing the silicon oxide film on the substrate surface and by etching back the film until the surfaces of the hard mask 11 and the LDD layers 8a, 8bare exposed. The source/drain layer 9a is formed by diffusing the N type impurity of high concentration, such as arsenic (As) ions, into the P-well 4a to a deep depth (essentially deeper than the LDD layer 8a) by an ion implantation method. The source/drain layer 9b is formed by diffusing the P type impurity of high concentration, such as boron (B) ions, into the N-well 4b, to a deep depth by an ion implantation method. In the step A6, the hard mask 11 is left over on the silicon layers 21a, 21b.

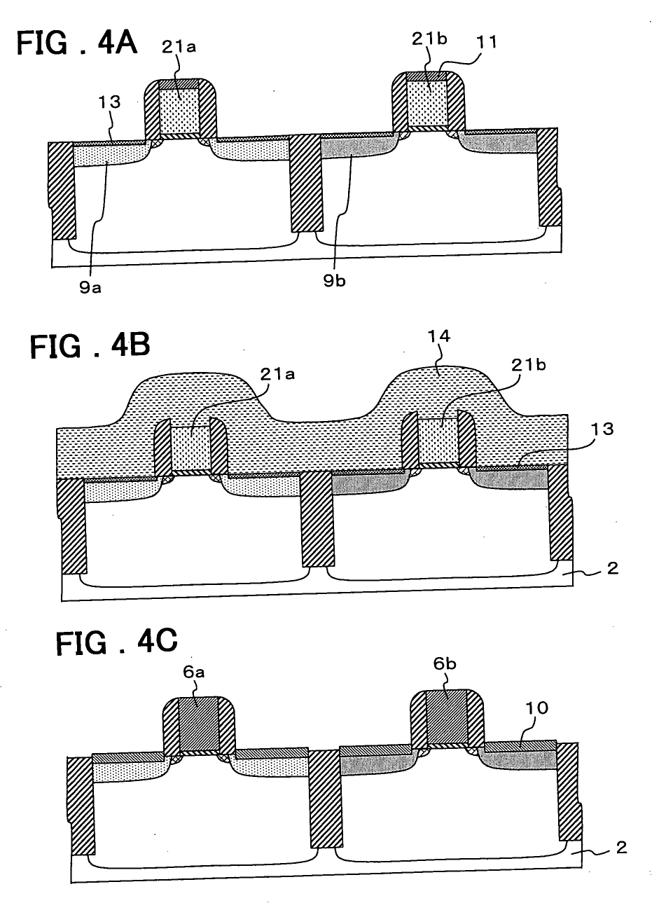

A silicidation suppressing component diffusion layer 13 is then formed by implanting a silicidation suppressing component into the surfacial part of the source/drain layers 9a, 9b (step A7, see FIG. 4A). It should be noted that the silicidation suppressing component diffusion layer 13 may be formed by implanting a silicidation suppressing component, such as Ge ions, into the source/drain layers 9a, 9b, by e.g. an ion implantation method. Since the hard mask 11 is left over in the step A7 on the silicon layers 21a, 21b, no Ge ions are implanted in the silicon layers 21a, 21b.

The hard mask (11 of FIG. 4A) is then selectively removed, and metal 14 is then deposited over the silicon substrate 2 inclusive of the silicon layers 21a, 21b and the silicidation suppressing component diffusion layer 13 (step A8, see FIG. 4B). It should be noted that the hard mask 11 may be selectively removed by a wet etching method. The metal 14 is, e.g. metal Ni deposited, e.g. by a sputtering method.

The film thickness of the metal 14 is such as will permit at least the silicon layers 21a, 21b to be silicided in their entirety and is not less than one-third of the thickness of the silicon layers 21a, 21b.

The silicon substrate 2, including the metal (14 of FIG. 4B), is heat-treated for siliciding, and subsequently, remaining non-reacted (non-silicided) metal is selectively removed (step A9, see FIG. 4C). By so doing, the gates 6a, 6b, in which the silicon layers (21a, 21b of FIG. 4B) have been metal-silicided in their entirety, are formed, at the same time as a metal silicide film 10 is formed by metal-silicidation of at least the silicidation suppressing component diffusion layer (13 of FIG. 4B). The metal silicide film 10, containing the silicidation suppressing component, such as Ge, is slow in its speed of being turned into metal silicide, and is formed to a thickness substantially thinner than the film thickness of the gates 6a, 6b. If, in the above step A2, impurities differing in type or concentration from one device forming layer to another are introduced into the silicon layer (21 of FIG. 2B), the reaction rate of metal silicidation of the silicon layer (21a, 21b of FIG. 4B) differs from one device forming layer to another, with a result that the gates 6a, 6b of different silicide structures, such as NiSi or NiSi², may be formed. It should be noted that the heat treatment conditions include annealing at 400° C., using, e.g. a ramp annealing method.

In the first embodiment, it is possible to prevent penetration of the metal silicide film 10 in the source/drain layers 9a, 9b or generation of leakage current. It is also possible to achieve a structure of a thin film thickness of the metal silicide film 10 on the source/drain layers 9a, 9b, by a simple method, together with a full silicidation of the gates 6a, 6b. That is, the complete (entire) silicidation of the gates 6a, 6b may be achieved by employing the conventional flow for CMOS fabrication. Moreover, since the difference in the reaction rate, ascribable to the silicidation suppressing component in the silicidation suppressing component diffusion layer 13, is exploited, it is unnecessary to perform a separate formation of the gates 6a, 6b (full silicide gates) from the formation of the metal silicide film 10 on the source/drain layers 9a, 9b. Additionally, the film thickness of the metal silicide film 10 on the source/drain layers 9a, 9b may be freely set by setting the film thickness of the silicidation suppressing component diffusion layer 13 and/or the concentration of the silicidation suppressing component.

### Second Embodiment

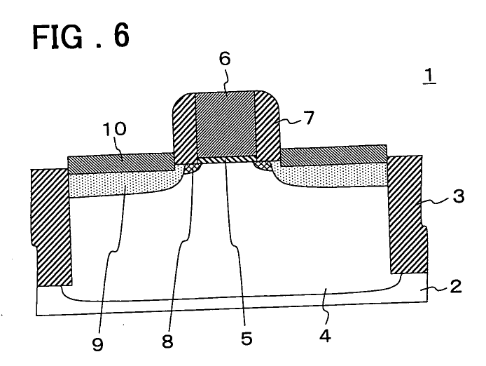

The second embodiment of the present invention will now be explained with reference to the drawings. FIG. 6 depicts a partial cross-sectional view schematically showing the configuration of a semiconductor device according to the second embodiment of the present invention.

In the semiconductor device of the second embodiment, the metal silicide film 10 is formed by metal silicidation of a silicidation adjustment film composed at least of a silicidation suppressing component, serving for suppressing the silicidation, such as Ge or As, and a silicon component. As in the first embodiment, the metal silicide film 10 is a metal silicide, which is a silicide of a high temperature melting metal, such as nickel (Ni), cobalt (Co), platinum (Pt), palladium (Pd) or rhodium (Rh). The film thickness of the metal silicide film 10 is thinner than the film thickness of the gate 6. Also, the film thickness of the metal silicide film 10 is thinner than the depth of junction of the source/drain layer 9, and a film thickness not less than 3 nm is sufficient as the film thickness of the metal silicide film 10. Otherwise, the configuration of the semiconductor device of the second embodiment is the same as the configuration of the semiconductor device of the first embodiment described above.

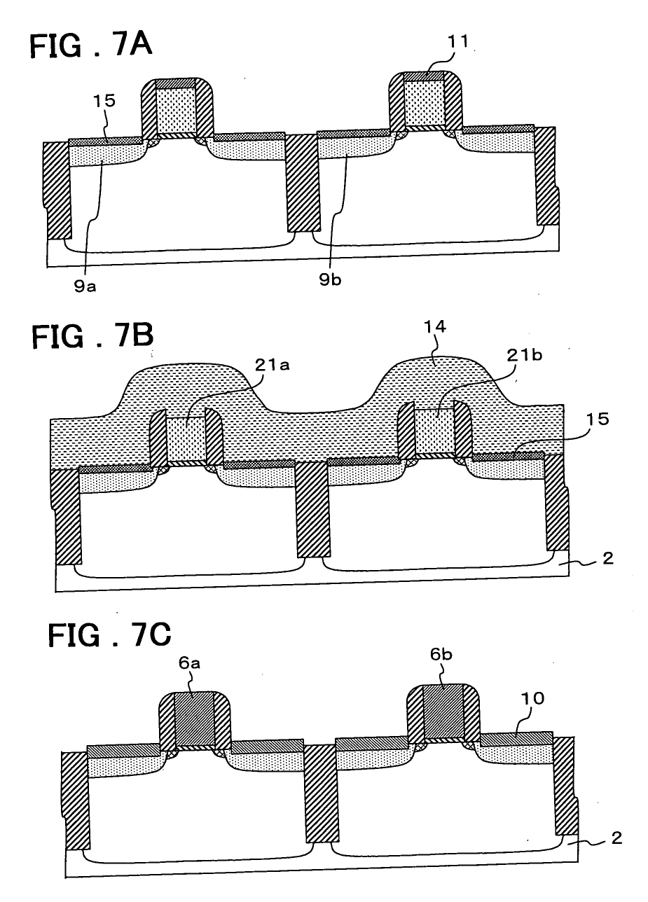

The method for the preparation of a semiconductor device of the second embodiment will now be explained. FIGS. 7A-7C are partial cross-sectional views schematically showing the method for the preparation of the semiconductor device according to the second embodiment of the present invention.

First, device separating regions 3, a P-well 4a and an N-well 4b are formed in preset locations on the silicon substrate 2 (step B1, see FIG. 2A). A gate insulating film 5 and a silicon layer 21 are formed (step B2, see FIG. 2B). A hard mask 11 and a photoresist 12 are formed (step B3, see FIG. 2C). The hard mask 11, silicon layer 21 and the gate insulating film 5 are etched off in an region exposed from the photoresist 12, until the silicon substrate 2, more precisely the wells 4a, 4b thereof, are exposed (step A4, see FIG. 3A). Subsequently, the photoresist is removed (step B4, see FIG. 3A). The LDD layers 8a, 8b are formed (step B5, see FIG. 3B), and sidewalls 7 as well as source/drain layers 9a, 9b are formed (step B6, see FIG. 3C). The steps B1 to B6 are similar to the steps A1 to A6 of the first embodiment (FIGS. 2A to FIG. 3C).

The source/drain layers 9a, 9b are then selectively etched back to a preset depth and, subsequently, a silicidation adjustment film 15 is selectively formed on the source/drain layers 9a, 9b (step B7, see FIG. 7A). In the etchback, the source/drain layers 9a, 9b are removed until a thickness less than the film thickness of the silicidation adjustment film 15 is reached, for example, up to the depth on the order of 5 nm. This selective etchback is carried out for preventing the sidewall 7 from being reduced in thickness for thereby suppressing the leakage at the sidewall 7. It should be noted that the silicidation adjustment film 15 is formed of a component for suppressing the silicidation, and the silicon component, and it is, e.g. SiGe. The silicidation adjustment film 15 may be formed to a film thickness of 5 nm by selectively allowing SiGe to grow on the source/drain layers 9a, 9b by the epitaxial method.

The hard mask (11 of FIG. 7A) is then selectively removed and, subsequently, the metal 14 is deposited over the entire silicon substrate 2, including the silicon layers 21a, 21b and the silicidation adjustment film 15 (step B8, see FIG. 7B). The metal 14 is, e.g. metal nickel Ni deposited by sputtering. The step B8 is similar to the step A8 of the first embodiment described above.

The silicon substrate 2, inclusive of the metal (14 of FIG. 7B), then is heat-treated for siliciding, and subsequently, remaining non-reacted metal is selectively removed (step B9, see FIG. 7C). By so doing, gates 6a, 6b are formed by the silicon layers (21a, 21b of FIG. 7B) being turned in its entirety into metal silicide, at the same time as the metal silicide film 10 is formed by at least the silicidation adjustment film 15 being turned into metal silicide. On the other hand, the metal silicide film 10, containing the silicidation suppressing component, such as Ge, is slow in its speed of being turned into metal silicide, and is formed to a thickness thinner than the film thickness substantially of the gates 6a, 6b. The step B9 is similar to the step A9 of the first embodiment described above.

The second embodiment displays favorable effects similar to those of the first embodiment. Moreover, full silicidation of the gates 6a, 6b and silicidation of the silicidation adjustment film 15 on the source/drain layers 9a, 9b may be carried out simultaneously by simply adding the step of forming the silicidation adjustment film 15 to the conventional flow of CMOS fabrication. The operations for forming a metal silicide film on the source/drain layers, such as PR or etching, are unnecessary to render it possible to reduce the number of process steps significantly. By forming the silicidation adjustment film 15 on the source/drain layers 9a, 9b, the problem of defects in implantation of silicidation suppressing components may be eliminated to suppress reliably the metal silicidation in the source/drain layers 9a, 9b. The result is that the leakage current such as junction leakage may be prevented more efficaciously from being produced to lower the power usage by the device. Moreover, by setting the film thickness of the silicidation adjustment film 15, the film thickness of the metal silicide film 10 on the source/drain layers 9a, 9b may be set freely.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
a gate formed only of a metal silicide; and
a metal silicide film formed on a source/drain layer, said metal silicide film being lesser in film thickness than said gate and containing a silicidation suppressing component for suppressing the silicidation of a silicon substrate.

2. A semiconductor device comprising:
a silicon substrate;
a source/drain layer formed so that a source and a drain are on both sides of a channel region of said silicon substrate;
a gate insulating film formed on said channel region;
a gate formed only of a metal silicide, and provided on said gate insulating film; and
a metal silicide layer thinner in the thickness than said gate;
said metal silicide layer being formed on said source/drain layer and containing a silicidation suppressing component for suppressing the silicidation of said silicon substrate.

3. The semiconductor device as defined in claim 1 wherein said silicidation suppressing component comprises germanium.

4. The semiconductor device as defined in claim 1 wherein the film thickness of said metal silicide layer is thinner than the depth of junction of said source/drain layer.

5. The semiconductor device as defined in claim 1 wherein said gate is a metal silicide obtained on silicidation of polysilicon or amorphous silicon with a preset metal.

6. The semiconductor device as defined in claim 1 wherein said gate is a metal silicide obtained on silicidation of polysilicon or amorphous silicon, into which has been introduced an impurity of the P type or the N type, with a preset metal.

7. The semiconductor device in claim 1 wherein the metal silicide of said gate and said metal silicide layer each contains at least one selected from group consisting of Ni, Co, Pt, Pd and Rh.

8. The semiconductor device as defined in claim 1 wherein said semiconductor device comprises a first device forming region and a second device forming region;
provided that wherein a gate formed in the first device forming region on said silicon substrate is of a silicide structure different from the silicide structure of a gate formed in the second device forming region on said silicon substrate different from said first device forming region.

9. The semiconductor device as defined in claim 1 wherein said gate formed in said first device forming region on said silicon substrate has an impurity component or an impurity concentration different from those of the other gate formed in the second device forming region on said silicon substrate different from said first device forming region.

10. A semiconductor device comprising:
a silicon substrate;
a source/drain layer formed so that a source and a drain are on both sides of a channel region of said silicon substrate;
a gate insulating film formed on said channel region;
a gate formed only of a metal silicide, and provided on said gate insulating film; and
a metal silicide layer thinner in the thickness than said gate;
said metal silicide layer being formed on said source/drain layer and containing a silicidation suppressing component for suppressing the silicidation of said silicon substrate;
said metal silicide layer having a thickness thinner than the depth of junction of said source/drain layer.

11. The semiconductor device as defined in claim 10 wherein said gate is a metal silicide obtained on silicidation of polysilicon or amorphous silicon with a preset metal.

12. A method for preparating a semiconductor device comprising the steps of:
selectively introducing a silicidation suppressing component, suppressing the silicidation, into at least one area of a source/drain layer;
coating at least a gate, formed of polysilicon or amorphous silicon, and said source/drain layer, with metal having a film thickness sufficient for silicidation of said gate in its entirety; and
metal-siliciding said gate in its entirety by heat treatment and also metal-siliciding at least said area of said source/drain layer into which has been introduced said silicidation suppressing component.

13. A method for preparing a semiconductor device comprising the steps of:
selectively forming a silicidation adjustment film, composed of silicidation suppressing component, suppressing the silicidation, and a silicon component, on at least one area of a source/drain layer;
coating at least a gate formed of polysilicon or amorphous silicon, and said silicidation adjustment film, with metal to a film thickness sufficient for silicidation of said gate in its entirety; and
metal-siliciding said gate in its entirety and simultaneously metal-siliciding at least said silicidation adjustment film, by heat treatment.

14. A method for preparing a semiconductor device comprising the steps of:
forming at least a region of device separating layer in a silicon substrate;
forming a gate insulating film in a channel region in said silicon substrate;
forming a gate of polysilicon or amorphous silicon on said gate insulating film;
forming a hard mask on said gate, said hard mask being formed of a material different in an etch rate from said device separating layer;
selectively forming a source/drain layer in said silicon substrate on both sides of said gate;
selectively introducing a silicidation suppressing component into said source/drain layer;
removing said hard mask;
coating at least said gate and said source/drain layer with metal of a film thickness at least sufficient for siliciding said gate in it entirety;
metal-siliciding said gate in its entirety and simultaneously metal-siliciding at least the area of said source/drain layer, into which said silicidation suppressing component has been introduced, by heat treatment; and
selectively removing a non-reacted portion of said metal.

15. A method for preparing a semiconductor device comprising the steps of:
forming at least a region of device separating layer in a silicon substrate;
forming a gate insulating film in a channel region in said silicon substrate;
forming a gate of polysilicon or amorphous silicon on said gate insulating film;
forming a hard mask on said gate, said hard mask being formed of a material different in an etch rate from said device separating layer;
selectively forming a source/drain layer in said silicon substrate on both sides of said gate;
selectively forming a silicidation adjustment film, containing a silicidation suppressing component for suppressing the silicidation of said silicon substrate, and a silicon component, on said source/drain layer;
removing said hard mask;
coating at least said gate and said silicidation adjustment film with metal to a film thickness sufficient for siliciding said gate in its entirety;
metal-siliciding said gate in its entirety and simultaneously metal-siliciding at least said silicidation adjustment film, by heat treatment; and
selectively removing a non-reacted portion of said metal.

16. The method for preparing a semiconductor device as defined in claim 15 further comprising, after the step of forming said source/drain layer and before the step of forming said silicidation adjustment film, a step of:
etching back at least said source/drain layer to a depth not larger than a thickness of said silicidation adjustment film.

17. The method for the preparation of a semiconductor device as defined in claim 14 further comprising, after said step of forming said gate and before said step of forming said hard-mask, a step of:
introducing an impurity of the P type or the N type into the entire or part of a region of said polysilicon or amorphous silicon for said gate.

18. The method for preparing a semiconductor device as defined in claim 17 wherein, in the step of introducing the impurity into said gate,
a first impurity is selectively introduced into a gate disposed in a first device forming region on said silicon substrate, and
a second impurity different from said first impurity is then selectively introduced into another gate disposed in a second device forming region different from said first device forming region on said silicon substrate.

19. The method for preparing a semiconductor device as defined in claim 17 wherein, in the step of introducing the impurity into said gate,
an impurity is selectively introduced into said gate disposed in a first device forming region on said silicon substrate, to a first impurity concentration, and
an impurity which is the same as the first-stated impurity is then selectively introduced into said other gate disposed in said second device forming region on said silicon substrate different from said first device forming region, to a second impurity concentration different from said first impurity concentration.

20. The method for preparing a semiconductor device as defined in claim 13 wherein said silicidation adjustment film is formed of SiGe.
